(19) United States
(12) Patent Application Publication
(10) Pub. No.: US 2025/0374539 A1
(43) Pub. Date: Dec. 4, 2025

(54) THREE-DIMENSIONAL VERTICAL NONVOLATILE MEMORY DEVICE INCLUDING MEMORY CELL STRING

(71) Applicant: Samsung Electronics Co., Ltd., Suwon-si (KR)

(72) Inventors: Yumin KIM, Suwon-si (KR); Garam PARK, Suwon-si (KR); Hyunjae SONG, Suwon-si (KR); Minhyun LEE, Suwon-si (KR); Seungdam HYUN, Suwon-si (KR)

(73) Assignee: Samsung Electronics Co., Ltd., Suwon-si (KR)

(21) Appl. No.: 18/914,643

(22) Filed: Oct. 14, 2024

(30) Foreign Application Priority Data
May 30, 2024 (KR) 10-2024-0071004

(51) Int. Cl. H10B 41/27; G11C 16/04; G11C 16/26; H10B 41/10; H10B 41/35

(52) U.S. Cl. CPC H10B 41/27; G11C 16/0483; G11C 16/26; H10B 41/10; H10B 41/35

(57) ABSTRACT

A three-dimensional vertical non-volatile memory device may include a plurality of memory cell strings, which each may include a channel layer extending in a first direction, a plurality of gate electrodes and a plurality of spacers alternately arranged in the first direction and each extending in a second direction intersecting the first direction, an ion reservoir layer extending in the first direction between the channel layer and the plurality of gate electrodes and between the channel layer and the plurality of spacers, and an electrolyte layer extending in the first direction between the channel layer and the ion reservoir layer. The ion reservoir layer and the channel layer may be configured to move ions such that ions may be moved from the ion reservoir layer to the channel layer or from the channel layer to the ion reservoir layer according to a voltage applied to the plurality of gate electrodes.

### CROSS-REFERENCE TO RELATED APPLICATION

This application claims the benefit of Korean Patent Application No. 10-2024-0071004, filed on May 30, 2024, in the Korean Intellectual Property Office, the disclosure of which is incorporated herein in its entirety by reference.

### BACKGROUND

### 1. Field

The disclosure relates to a three-dimensional vertical non-volatile memory device including a memory cell string.

### 2. Description of the Related Art

A non-volatile memory device, as a semiconductor memory device, includes a plurality of memory cells that can retain information even in a power-off state and use the stored information again when power is supplied thereto. Non-volatile memory devices may be used in mobile phones, digital cameras, personal digital assistants (PDAs), portable computer devices, stationary computer devices, and other devices.

An example of a non-volatile memory device includes a vertical NAND (VNAND). VNAND is a memory device with increased integration by vertically stacking a large number of memory cells. Various technologies have been proposed to realize high capacity in the same region by increasing the number of VNAND stacks. For example, in order to implement VNAND, various technologies, for example, methods using charge traps, methods using phase change materials, methods using resistance change materials, methods using ferroelectrics, and the like, have been proposed. Furthermore, various materials have been researched to improve the performance of a non-volatile memory device, for example, improvement of data reliability, improvement of a driving speed, reduction of consumption power, increase of a degree of integration, and the like.

### SUMMARY

Provided is a three-dimensional vertical non-volatile memory device including a memory cell string.

Additional aspects will be set forth in part in the description which follows and, in part, will be apparent from the description, or may be learned by practice of the presented embodiments.

According to an example embodiment of the disclosure, a three-dimensional vertical non-volatile memory device may include a plurality of memory cell strings. The plurality of memory cell strings each may include a channel layer extending in a first direction, a plurality of gate electrodes and a plurality of spacers alternately arranged in the first direction and each extending in a second direction, the second direction intersecting the first direction, an ion reservoir layer extending in the first direction between the channel layer and the plurality of gate electrodes and between the channel layer and the plurality of spacers, and an electrolyte layer extending in the first direction between the channel layer and the ion reservoir layer. The ion reservoir layer and the channel layer may be configured to move ions to each other such that ions may be moved from the ion reservoir layer to the channel layer or from the channel layer to the ion reservoir layer according to a voltage applied to the plurality of gate electrodes.

In some embodiments, the ion reservoir layer and the electrolyte layer each may include a metal oxide material.

In some embodiments, a concentration of oxygen vacancy in the ion reservoir layer may be greater than a concentration of oxygen vacancy in the electrolyte layer.

In some embodiments, a composition of the ion reservoir layer may be stoichiometrically deficient in oxygen.

In some embodiments, a ratio of oxygen in a material of the electrolyte layer may be greater than a ratio of oxygen in a material of the ion reservoir layer.

In some embodiments, the metal oxide material of the ion reservoir layer may include at least one of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx). The metal oxide material of the electrolyte layer may include at least one of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx).

In some embodiments, the channel layer may include at least one of indium-gallium-zinc oxide (IGZO), indium-zinc oxide (IZO), gallium-zinc oxide (GZO), zinc-tin oxide (ZTO), indium tungsten oxide (IWO), tungsten oxide (WOx), and zinc oxide (ZnOx).

In some embodiments, the thickness of the channel layer in the second direction may be in a range from 2 nm to 10 nm.

In some embodiments, the thickness of the ion reservoir layer in the second direction may be a range from 2 nm to 10 nm.

In some embodiments, the thickness of the electrolyte layer in the second direction may be less than the thickness of the ion reservoir layer in the second direction.

In some embodiments, the plurality of memory cell strings may further include a barrier layer extending in the first direction between the plurality of gate electrodes and the ion reservoir layer and between the plurality of spacers and the ion reservoir layer.

In some embodiments, the barrier layer may include at least one material of silicon oxide (SiO₂), silicon nitride (SiN), silicon oxynitride (SiON), and metal oxide.

In some embodiments, the thickness of the barrier layer in the second direction may be greater than 0 nm and less than or equal to 10 nm.

In some embodiments, when a write voltage that is positive is applied to one of the plurality of gate electrodes, ions in a partial region of the ion reservoir layer may pass through the electrolyte layer and may move to a partial region of the channel layer and the partial region of the channel layer may have a first resistance. The partial region of the ion reservoir layer may be adjacent in the second direction to the one of the plurality of gate electrodes to which the write voltage is applied. The partial region of the channel layer may be adjacent in the second direction to the one of the plurality of gate electrodes to which the write voltage is applied.

In some embodiments, when a erase voltage that is negative is applied to the one of the plurality of gate electrodes, ions in the partial region of the channel layer may pass through the electrolyte layer and may move to the partial region of the ion reservoir layer, and the partial region of the channel layer may have a second resistance. The second resistance may be greater than the first resistance.

In some embodiments, the electrolyte layer may be configured such that, when a gate electrode among the plurality of gate electrodes is in a floating state, ions are not moved between a region of the ion reservoir layer and a region of the channel layer adjacent in the second direction to the gate electrode in the floating state.

In some embodiments, the electrolyte layer may be configured such that, when a gate electrode among the plurality of gate electrodes is in a floating state, ions may not move between a region of the ion reservoir layer and a region of the channel layer adjacent in the second direction to the gate electrode in the floating state.

In some embodiments, the three-dimensional non-volatile memory device may be configured to perform a read operation when a read voltage that is positive is applied to only a selected one of the plurality of gate electrodes and a pass voltage that is positive is applied to non-selected gate electrodes among the plurality of gate electrodes. The selected one of the plurality of gate electrodes may correspond to a selected memory cell in one of the plurality of memory cell strings from which date is to be read. The non-selected gate electrodes may correspond to non-selected memory cells in the one of the plurality of memory cell strings. The read voltage may be greater than the erase voltage. The pass voltage may be greater than the read voltage. The write voltage may be greater than the pass voltage.

In some embodiments, when the read voltage may be applied to the plurality of gate electrodes and the channel layer has the first resistance, a low resistance current may flow in the channel layer having the first resistance. When the read voltage may be applied to the plurality of gate electrodes and the channel layer has the second resistance, and a high resistance current may flow in the channel layer having the second resistance. When the pass voltage may be applied to the plurality of gate electrodes and the channel layer has either the first resistance or the second resistance, a same pass current may flow in the channel layer having either the first resistance or the second resistance.

In some embodiments, the low resistance current may be greater than the high resistance current, and the pass current may be greater than the high resistance current.

In some embodiments, the write voltage may include a first write voltage and a second write voltage. The second write voltage may be greater than the first write voltage. When the first write voltage is applied to one of the plurality of gate electrodes, a partial region of the channel layer adjacent in the second direction to the one of the plurality of gate electrodes to which the first write voltage is applied may have a first-1 resistance. When the second write voltage is applied to one of the plurality of gate electrodes, a partial region of the channel layer adjacent in the second direction to the one of the plurality of gate electrodes to which the second write voltage is applied may have a first-2 resistance. The first-2 resistance may be less than the first-1 resistance.

According to an example embodiment of the disclosure, an electronic device may include processing circuitry; and a three-dimensional vertical non-volatile memory device connected to the processing circuitry. The three-dimensional vertical non-volatile memory device may include a plurality of memory cell strings. The plurality of memory cell strings may include a channel layer extending in a first direction, a plurality of gate electrodes and a plurality of spacers alternately arranged in the first direction and each extending in a second direction, the second direction intersecting the first direction, an ion reservoir layer extending in the first direction between the channel layer and the plurality of gate electrodes and between the channel layer and the plurality of spacers, and an electrolyte layer extending in the first direction between the channel layer and the ion reservoir layer. The ion reservoir layer and the channel layer may be configured to move ions such that ions are moved from the ion reservoir layer to the channel layer or from the channel layer to the ion reservoir layer, according to a voltage applied to the plurality of gate electrodes.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram of a memory system according to an embodiment;

FIG. 2 is a block diagram showing an implementation example of a memory device illustrated in FIG. 1;

FIG. 3 is a schematic block diagram of a memory cell array illustrated in FIG. 1;

FIG. 4 is an equivalent circuit corresponding to a memory block according to an embodiment;

FIG. 5 is a vertical cross-sectional view schematically showing a structure of a memory cell string according to an embodiment;

FIG. 6 is a horizontal cross-sectional view schematically showing a structure of a memory cell string according to an embodiment;

FIG. 7 is a view showing an example of a SET operation of a memory cell string, according to an embodiment;

FIG. 8 is a view showing an example of a RESET operation of a memory cell string, according to an embodiment;

FIGS. 9 and 10 are views showing examples of a read operation on a selected memory cell of a memory cell string according to an embodiment;

FIG. 11 is a graph showing an example of a driving voltage and voltage-current properties of one memory cell of a memory cell string according to an embodiment;

FIG. 12 is a graph showing an example of voltage-current properties after the SET operation of one memory cell of a memory cell string according to an embodiment;

FIG. 13 is a vertical cross-sectional view schematically showing a structure of a memory cell string according to another embodiment;

FIG. 14 is a schematic conceptual view of a device architecture applicable to an example electronic device including a memory device according to an embodiment; and

FIG. 15 is a schematic block diagram of a neuromorphic apparatus including a memory device according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a three-dimensional vertical non-volatile memory device including a memory cell string will be described in detail with reference to the accompanying drawings. Throughout the drawings, like reference numerals denote like elements, and sizes of components in the drawings may be exaggerated for convenience of explanation and clarity. Furthermore, as embodiments described below are examples, other modifications may be produced from the embodiments.

When a constituent element is disposed “above” or “on” to another constituent element, the constituent element may be only directly on the other constituent element or above the other constituent elements in a non-contact manner. As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or components, but do not preclude the presence or addition of one or more other features or components.

The use of the terms “a,” “an,” “the,” and similar referents in the context of describing the disclosure are to be construed to cover both the singular and the plural. Also, the operations of all methods described herein can be performed in any suitable order unless otherwise indicated herein or otherwise clearly contradicted by context. The disclosure is not limited to the described order of the steps.

Furthermore, terms such as “ . . . portion,” “ . . . unit,” “ . . . module,” and “ . . . block” stated in the specification may signify a unit to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language (e.g., “such as”) provided herein, is intended merely to better illuminate the disclosure and does not pose a limitation on the scope of the disclosure unless otherwise claimed.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

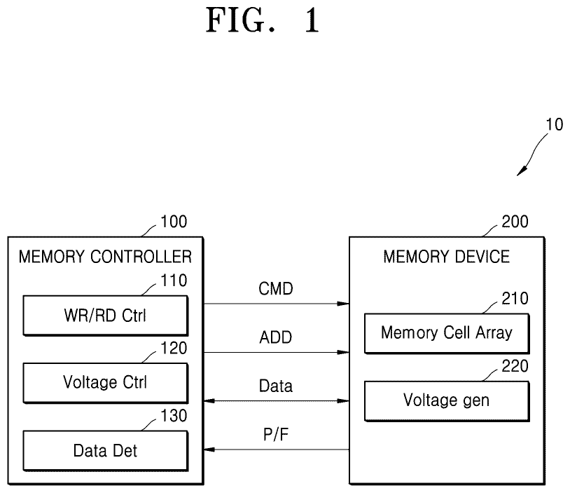

FIG. 1 is a block diagram of a memory system 10 according to an embodiment. Referring to FIG. 1, the memory system 10 according to an embodiment may include a memory controller 100 and a memory device 200. The memory controller 100 may perform a control operation on the memory device 200. In an example, the memory controller 100 may perform a program (or write), read, or erase operation on the memory device 200 by providing an address ADD and a command CMD to the memory device 200. Furthermore, data for a program operation and read data may be transceived between the memory controller 100 and the memory device 200. The memory device 200 may provide a pass/fail signal to the memory controller 100 according to a read result of the read data, and the memory controller 100 may control a write/read operation on a memory cell array 210 in response to the pass/fail signal.

The memory device 200 may include the memory cell array 210 and a voltage generator 220. The memory cell array 210 may include a plurality of memory cells arranged in regions where a plurality of word lines and a plurality of bit lines cross each other. The memory cell array 210 may include non-volatile memory cells that non-volatilely store data, and as non-volatile memory cells, the memory cell array 210 may include flash memory cells, such as a NAND flash memory cell array, a NOR flash memory cell array, or the like. In the following description, embodiments of the disclosure are described assuming that the memory cell array 210 includes a flash memory cell array, and thus, the memory device 200 is a non-volatile memory device.

The memory controller 100 may include a write/read controller 110, a voltage controller 120, and a data determination unit 130.

The write/read controller 110 may generate the address ADD and the command CMD to perform program/read and erase operations on the memory cell array 210. Furthermore, the voltage controller 120 may generate a voltage control signal to control at least one voltage level used in the memory device 200 that is non-volatile. For example, the voltage controller 120 may generate a voltage control signal to control a voltage level of a word line to read data from the memory cell array 210 or program data to the memory cell array 210.

The data determination unit 130 may perform a determination operation on the data read from the memory device 200. For example, by determining the data read from the memory cells, the data determination unit 130 may determine the number of on-cells and/or off-cells among the memory cells. As an example operation, when a program is performed on a plurality of memory cells, by determining a state of data of the memory cells using a certain read voltage, whether the program is normally completed for all cells may be determined.

As described above, the memory cell array 210 may include non-volatile memory cells, for example, flash memory cells. Furthermore, the flash memory cells may be implemented in various forms. For example, the memory cell array 210 may include three-dimensional (or vertical) NAND (VNAND) memory cells.

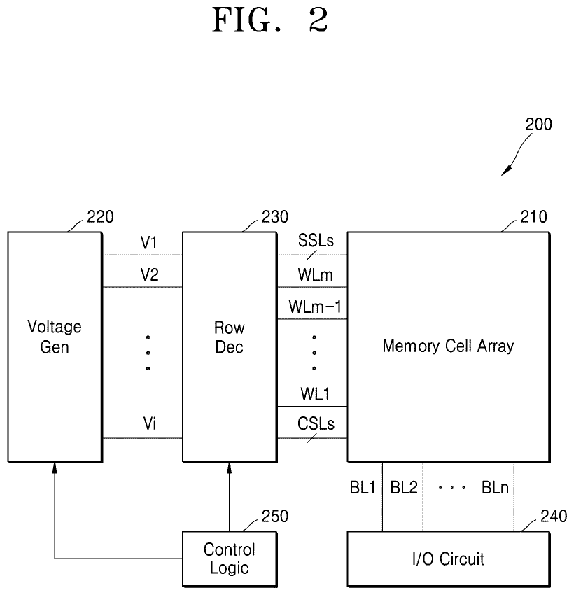

FIG. 2 is a block diagram showing an implementation example of a memory device 200 illustrated in FIG. 1. Referring to FIG. 2, the memory device 200 may include a row decoder 230, an input/output circuit 240, and a control logic 250.

The memory cell array 210 may be connected to one or more string select lines SSLs, a plurality of word lines WL1 to WLm, and one or more common source lines CSLs, and furthermore, to a plurality of bit lines BL1 to BLn. The voltage generator 220 may generate one or more word line voltages V1 to Vi, and the word line voltages V1 to Vi may be provided to the row decoder 230. Signals for program/read/erase operations may be applied to the memory cell array 210 through the bit lines BL1 to BLn.

Furthermore, data to be programmed may be provided to the memory cell array 210 through the input/output circuit 240, and data that is read may be provided to the outside (e.g., the memory controller 100) through the input/output circuit 240. The control logic 250 may provide various control signals related to memory operations to the row decoder 230 and the voltage generator 220.

The word line voltages V1 to Vi may be provided through various lines (SSLs, WL1 to WLm, CSLs) according to a decoding operation of the row decoder 230. For example, the word line voltages V1 to Vi may include a string select voltage, a word line voltage, and a ground select voltage, and the string select voltage may be provided to the string select lines SSLs, the word line voltage may be provided to the word lines WL1 to WLm, and the ground select voltage may be provided to the common source lines CSLs.

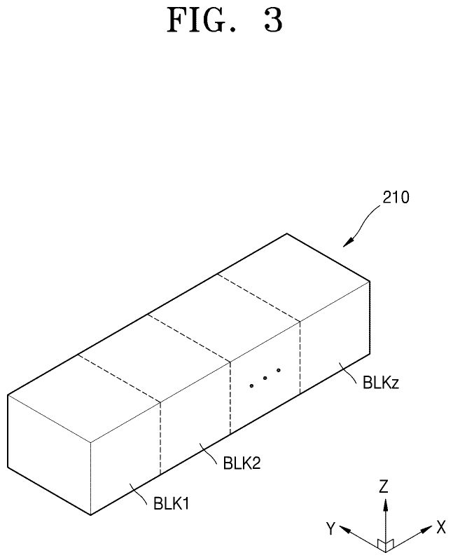

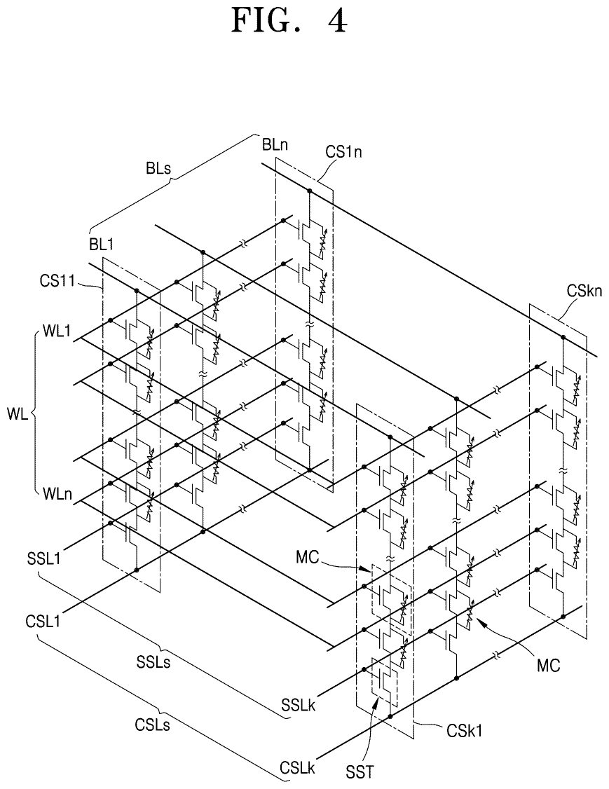

FIG. 3 is a schematic block diagram of the memory cell array 210 illustrated in FIG. 1. Referring to FIG. 3, the memory cell array 210 may include a plurality of memory blocks BLK1 to BLKz. Each memory block BLK may have a three-dimensional structure (or a vertical structure). For example, each memory block BLK may include a structure extending in first to third directions. For example, each memory block BLK may include a plurality of memory cell strings extending in the first direction (Z direction). Accordingly, the plurality of memory cell strings may have a three-dimensional vertical structure. In this point, the memory device 200 may be a three-dimensional vertical non-volatile memory device. Each memory cell string is connected to the bit line BL, the string select line SSL, the word lines WLs, and the common source line CSL. Accordingly, the memory blocks BLK1 to BLKz may be respectively connected to the bit lines BLs, the string select lines SSLs, the word lines WLs, and the common source lines CSLs. The memory blocks BLK1 to BLKz configured as above are described in detail with reference to FIG. 4.

FIG. 4 is an equivalent circuit corresponding to a memory block according to an embodiment. For example, FIG. 4 illustrates one of the memory blocks BLK1 to BLKz of the memory cell array 210 of FIG. 3. Referring to FIGS. 3 and 4, the memory blocks BLK1 to BLKz may each include a plurality of memory cell strings CS11 to CSkn. The memory cell strings CS11 to CSkn may be arranged two-dimensionally in a row direction and a column direction to thus form rows and columns. Each of the memory cell strings CS11 to CSkn may include a plurality of memory cells MCs and a plurality of string select transistors SSTs. The memory cells MCs and the string select transistors SSTs of each of the memory cell strings CS11 to CSkn may be stacked in a height direction.

Rows of the memory cell strings CS11 to CSkn are connected to different string select lines SSL1 to SSLk, respectively. For example, the string select transistors SSTs of the memory cell strings CS11 to CSIn are connected in common to the string select line SSL1. The string select transistors SSTs of the memory cell strings CSK1 to CSkn are connected in common to the string select line SSLk.

Furthermore, the columns of the memory cell strings CS11 to CSkn are connected to different bit lines BL1 to BLn, respectively. For example, the memory cells MCs and the string select transistors SSTs of the memory cell strings CS11 to CSk1 may be connected in common to the bit line BL1, and the memory cells MCs and the string select transistors SSTs of the memory cell strings CSIn to CSkn may be connected in common to the bit line BLn.

Furthermore, rows of the memory cell strings CS11 to CSkn may be connected to different common source lines CSL1 to CSLk, respectively. For example, the string select transistors SSTs of the memory cell strings CS11 to CSIn may be connected in common to the common source line CSL1, and the string select transistors SSTs of the memory cell strings CSk1 to CSkn may be connected in common to the common source line CSLk.

The memory cells MCs located at the same height from a substrate (or the string select transistors SSTs) may be connected in common to one word line WL, and the memory cells MCs located at different heights may be connected to different word lines WL1 to WLm, respectively.

The memory block illustrated in FIG. 4 is an example. The technical concept of the disclosure is not limited to the memory block illustrated in FIG. 4. For example, the number of rows of the memory cell strings CS11 to CSkn may be increased or decreased. As the number of rows of the memory cell strings CS11 to CSkn is changed, the number of string select lines SSL1 to SSLk connected to the rows of the memory cell strings CS11 to CSkn, and the number of memory cell strings CS11 to CSkn connected to one bit line, may also be changed. As the number of rows of the memory cell strings CS11 to CSkn is changed, the number of common source lines CSL1 to CSLk connected to the rows of the memory cell strings CS11 to CSkn may also be changed. Furthermore, the number of columns of the memory cell strings CS11 to CSkn may be increased or decreased. As the number of columns of the memory cell strings CS11 to CSkn is changed, the number of bit lines BL1 to BLn connected to the columns of the memory cell strings CS11 to CSkn, and the number of memory cell strings CS11 to CSkn connected to one string select line SSL, may also be changed.

The height of each of the memory cell strings CS11 to CSkn may be increased or decreased. For example, the number of memory cells MCs stacked on each of the memory cell strings CS11 to CSkn may be increased or decreased. As the number of memory cells MCs stacked on each of the memory cell strings CS11 to CSkn is changed, the number of word lines WLs may also be changed. For example, the number of string select transistors SSTs provided to each of the memory cell strings CS11 to CSkn may be increased. As the number of string select transistors SSTs provided to each of the memory cell strings CS11 to CSkn is changed, the number of string select lines SSL or common source lines CSLs may also be changed. As the number of string select transistors SSTs is increased, the string select transistors SSTs may be stacked in the same form as the memory cells MCs.

For example, the write and read operations may be performed for each row of the memory cell strings CS11 to CSkn. The memory cell strings CS11 to CSkn may be selected for each row by the common source lines CSLs, and the memory cell strings CS11 to CSkn may be selected for each row by the string select lines SSLs. In a selected row of the memory cell strings CS11 to CSkn, the write and read operations may be performed for each page. For example, a page may be one row of the memory cells MCs connected to one word line WL. The memory cells MCs may be selected for each page by the word lines WL in the selected row of the memory cell strings CS11 to CSkn.

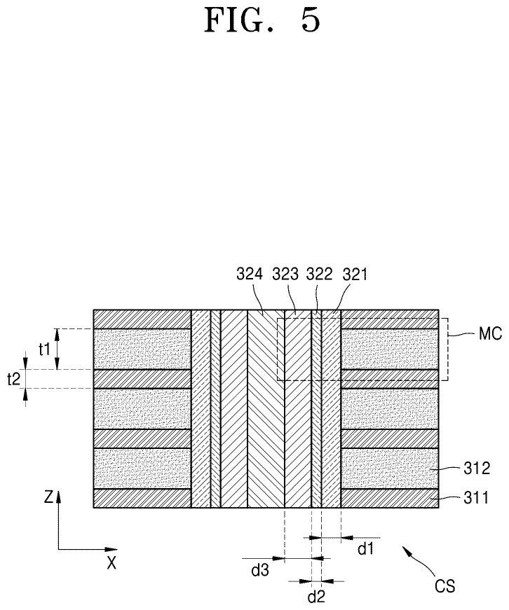

The memory cells MCs in each of the memory cell strings CS11 to CSkn may correspond to a circuit in which a transistor and a resistor are connected in parallel. For example, FIG. 5 is a schematic vertical cross-sectional view of a structure of each memory cell string CS according to an embodiment. Referring to FIG. 5, the memory cell string CS may include a plurality of insulating spacers 311 and a plurality of gate electrodes 312, which are alternatively stacked in a vertical direction, that is, in the first direction (Z direction) perpendicularly crossing the second direction (X direction). The insulating spacers 311 and the gate electrodes 312 may extend in a horizontal direction, that is, the second direction. Each gate electrode 312 may be connected to the word line WL, or each gate electrode 312 may be the word line WL, as it is.

The insulating spacers 311 may include one of various insulating dielectric materials, for example, a silicon oxide, an aluminum oxide, a silicon nitride, and the like, but the disclosure is not limited thereto. The gate electrode 312 may include at least one of conductive materials, such as tungsten (W), molybdenum (Mo), ruthenium (Ru), polysilicon, TiN, and a two-dimensional metallic material, or a combination thereof. The two-dimensional metallic material may include at least one material, such as, graphene, TaS₂, TaSe₂, NbS₂, NbSe₂, PdTe₂, PtTe₂, NbTe₂, TiSe₂, VSe₂, AuSe, and MoTe₂.

Furthermore, the memory cell string CS may include a channel hole that penetrates the insulating spacers 311 and the gate electrodes 312 in the first direction. A channel and a plurality of layers for forming resistance may be arranged in the channel hole. For example, the memory cell string CS may include an insulating support 324 arranged at the center of the channel hole and extending in the first direction, a channel layer 323 arranged to surround the insulating support 324 and extending in the first direction, an electrolyte layer 322 arranged to surround the channel layer 323 and extending in the first direction, and an ion reservoir layer 321 arranged to surround the electrolyte layer 322 and extending in the first direction. The ion reservoir layer 321 may be arranged between the channel layer 323 and the gate electrodes 312 and between the channel layer 323 and the insulating spacers 311. Furthermore, the electrolyte layer 322 may be arranged between the channel layer 323 and the ion reservoir layer 321.

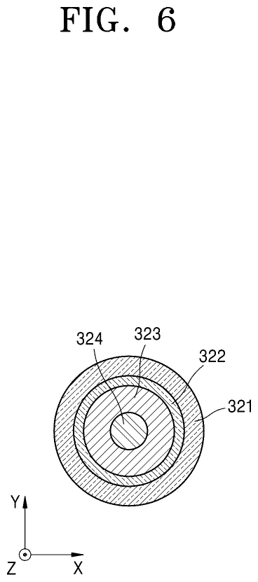

FIG. 6 is a horizontal cross-sectional view schematically showing a structure of a memory cell string CS according to an embodiment. Referring to FIG. 6, the insulating support 324, the channel layer 323, the electrolyte layer 322, and the ion reservoir layer 321 may be disposed sequentially arranged concentrically from the center of the channel hole. The ion reservoir layer 321 may have a cylindrical shape surrounding the electrolyte layer 322, the electrolyte layer 322 may have a cylindrical shape surrounding the channel layer 323, and the channel layer 323 may have a cylindrical shape surrounding the insulating support 324. Although not illustrated in FIG. 6, the insulating spacers 311 and the gate electrodes 312 may be alternatively stacked in the first direction while surrounding the ion reservoir layer 321.

To this end, the ion reservoir layer 321 may be conformally deposited on the insulating spacers 311 and the gate electrodes 312 to extend in the first direction. The electrolyte layer 322 may be conformally deposited along a surface of the ion reservoir layer 321 to extend in the vertical direction, that is, in the first direction. The channel layer 323 may be conformally deposited along the surface of the electrolyte layer 322 to extend in the first direction. The insulating support 324 may be arranged to fill the remaining space in the center of the channel hole to extend in the first direction.

As a result, the channel layer 323 has a shape extending in the first direction facing the insulating spacers 311 and the gate electrodes 312, the electrolyte layer 322 has a shape extending in the first direction between the channel layer 323 and the gate electrodes 312, and the ion reservoir layer 321 has a shape extending in the first direction between the electrolyte layer 322 and the gate electrodes 312.

Although it is not illustrated, a drain may be arranged on the uppermost surface of the memory cell string CS to cover an upper surface of at least the channel layer 321. The drain may include a doped semiconductor material. The drain may be electrically connected to an upper portion of the channel layer 321. Furthermore, the bit line BL may be connected to the drain. A source may be disposed on a lower surface of the channel layer 321. The source may include a doped semiconductor material. The source may be electrically connected to the lower portion of the channel layer 321. Furthermore, the common source line CSL may be connected to the source.

According to an embodiment, ion exchange may occur between the channel layer 323 and the ion reservoir layer 321 according to a program voltage (e.g., a write voltage) or erase voltage applied to the gate electrodes 312. For example, when a write voltage is applied to the gate electrodes 312, ions are moved from the ion reservoir layer 321 to the channel layer 323 so that the ion concentration in the channel layer 323 may increase. In this case, the resistance of the channel layer 323 may be reduced. Reversely, when an erase voltage is applied to the gate electrodes 312, ions are moved from the channel layer 323 to the ion reservoir layer 321 so that the ion concentration in the channel layer 323 may decrease. In this case, the resistance of the channel layer 323 may be increased. Accordingly, the channel layer 323 may have both a current path function and a resistance change layer function. The electrolyte layer 322 may function as an ion movement path between the channel layer 323 and the ion reservoir layer 321 when a write voltage or an erase voltage is applied to the gate electrodes 312, and prevent or reduce ion exchange between the channel layer 323 and the ion reservoir layer 321 when no write voltage or no erase voltage is applied to the gate electrodes 312.

In an embodiment, ions may be donor ions that function as a donor to provide electrons. For example, the donor ions may be oxygen vacancy (also referred to as oxygen vacancies). The ion reservoir layer 321 and the electrolyte layer 322 may each include a metal oxide material that includes a large amount of donor ions like oxygen vacancy or easily receives/releases donor ions. For example, the ion reservoir layer 321 and the electrolyte layer 322 may each include at least one of material of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx). The ion reservoir layer 321 and the electrolyte layer 322 may include the same material or different materials.

In order for the ion reservoir layer 321 to include donor ions (e.g., oxygen vacancy) at a high concentration, a ratio of oxygen within the material of the ion reservoir layer 321 may be less than a ratio of oxygen within the material of the electrolyte layer 322. For example, the ion reservoir layer 321 may have a composition stoichiometrically deficient in oxygen. In contrast, the electrolyte layer 322 may have a composition that is not stoichiometrically deficient in oxygen. When the ion reservoir layer 321 and the electrolyte layer 322 each include at least one of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx), an x value of the electrolyte layer 322 may be greater than an x value of the ion reservoir layer 321. Accordingly, a ratio of oxygen within the material of the electrolyte layer 322 may be greater than a ratio of oxygen within the material of the ion reservoir layer 321. In other words, a concentration of the donor ions (e.g., oxygen vacancy) within the ion reservoir layer 321 may be greater than a concentration of the donor ions (e.g., oxygen vacancy) within the electrolyte layer 322. In the following description, the donor ions are briefly referred to as the ions. In other words, a ratio of oxygen to total elements within the material of the electrolyte layer 322 may be greater than a ratio of oxygen to total elements within the material of the ion reservoir layer 321.

The channel layer 323 may include a material that easily receives/releases ions (e.g., oxygen vacancy) and changes electrical resistance depending on the concentration of ions. To this end, the channel layer 323 may include an oxide semiconductor material or a metal oxide material. For example, the channel layer 323 may include at least one of oxide semiconductor materials, such as indium-gallium-zinc oxide (IGZO), indium-zinc oxide (IZO), gallium-zinc oxide (GZO), zinc-tin oxide (ZTO), indium tungsten oxide (IWO), tungsten oxide (WOx), and zinc oxide (ZnOx). When the channel layer 323 includes tungsten oxide (WOx) or zinc oxide (ZnOx), the oxygen composition in tungsten oxide (WOx) or zinc oxide (ZnOx) may be selected so that the channel layer 323 has the properties of an oxide semiconductor. The oxygen composition in tungsten oxide (WOx) or zinc oxide (ZnOx) used in the channel layer 323 may be different from the oxygen composition in tungsten oxide (WOx) or zinc oxide (ZnOx) used as the ion reservoir layer 321 or the electrolyte layer 322. Furthermore, when the channel layer 323 includes a metal oxide, the metal oxide material of the channel layer 323 may be different from the metal oxide material of the electrolyte layer 322.

Referring back to FIG. 5, as indicated by the dashed box, any one of the gate electrodes 312, and a portion of the ion reservoir layer 321, a portion of the electrolyte layer 322, and a portion of the channel layer 323, which are adjacent to one another in the horizontal direction, that is, the second direction, with respect to the one of the gate electrodes 312, may form one memory cell MC. For example, one gate electrode 312, and the portion of the ion reservoir layer 321, the portion of the electrolyte layer 322, and the portion of the channel layer 323, which are adjacent to the gate electrode 312 in the horizontal direction, may form a transistor. The portion of the channel layer 323 may also form a resistor. In this point, the channel layer 323 may perform both functions of a channel of a transistor and a resistance change layer. Accordingly, each of the memory cells MCs may correspond to a circuit in which a transistor and a resistor are connected in parallel. Such memory cells MCs are arranged in a vertical stack structure to thus form each memory cell string CS. According to an embodiment, as an oxide material having relatively high electrical conductivity compared with polysilicon (p-Si) is used as the channel layer 323, the number of memory cells MCs stackable in the memory cell string CS may be increased.

The thickness of one memory cell MC may be determined by a first direction height t1 of one of the gate electrodes 312, and an interval between the two memory cells MCs adjacent in the first direction may be determined by a first direction height t2 of one of the insulating spacers 311. The degree of integration of the memory cell MC may be increased by reducing the first direction height t2 of one insulating spacer 311 or the interval between the two adjacent gate electrodes 312 in the first direction. For example, the first direction height t1 of one of the gate electrodes 312 may be about 20 nm or less. According to an embodiment, as a driving voltage applied to each of the gate electrodes 312 is relatively low, the first direction height t2 of one insulating spacer 311 may be reduced. For example, the first direction height t2 of one insulating spacer 311 may be about 15 nm or less, about 10 nm or less, or about 8 nm or less.

A thickness d1 of the ion reservoir layer 321 in the second direction may be, for example, about 2 nm to about 10 nm. A thickness d2 of the electrolyte layer 322 in the second direction may be, for example, about 1 nm to about 10 nm. Furthermore, a thickness d3 of the channel layer 323 in the second direction may be, for example, about 2 nm to about 10 nm. In order to facilitate ion exchange between the ion reservoir layer 321 and the channel layer 323, the thickness d2 of the electrolyte layer 322 in the second direction may be less than the thickness d1 of the ion reservoir layer 321 in the second direction. For example, the thickness d2 of the electrolyte layer 322 in the second direction may be about 1 nm to 5 nm.

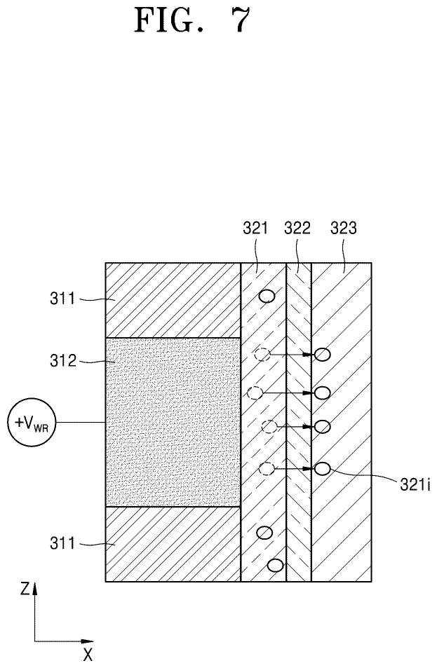

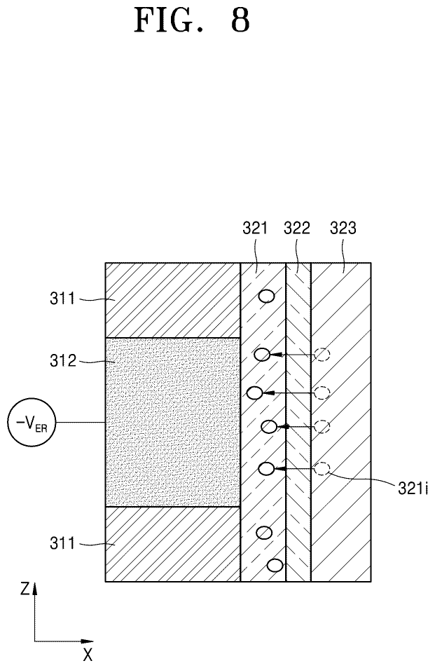

According to an embodiment, a SET operation and a RESET operation in the memory cell string CS may be independently performed for each memory cell MC of the memory cell string CS. FIG. 7 is a view showing an example of a SET operation of the memory cell string CS, according to an embodiment, and FIG. 8 is a view showing an example of a RESET operation of the memory cell string CS, according to an embodiment. FIGS. 7 and 8 illustrate only the left part of the insulating support 324 of FIG. 5, for convenience.

Referring to FIG. 7, a positive (+) write voltage V_{WR} may be applied, through the word line WL, to the gate electrode 312 of a memory cell, on which a SET operation is to be performed, among the gate electrodes 312. Then, ions 321i in a partial region of the ion reservoir layer 321 adjacent in the second direction to the gate electrode 312 to which the positive (+) write voltage V_{WR} is applied may pass through the electrolyte layer 322 to move to a partial region of the channel layer 323 adjacent in the second direction to the gate electrode 312 to which the positive (+) write voltage V_{WR} is applied. As described above, the ions 321i may be donor ions like oxygen vacancy. Accordingly, the concentration of donor ions such as oxygen vacancy increase within the channel layer 323. For example, when the partial region of the channel layer 323 has a first ion concentration that is relatively high, the partial region of the channel layer 323 has a first resistance that is relatively low or a first electrical conductivity that is relatively high. In this case, a transistor including the corresponding gate electrode 312, and the portion of the ion reservoir layer 321, the portion of the electrolyte layer 322, and the portion of the channel layer 323, which are adjacent to one another in the second direction with respect to the gate electrode 312, may have a first threshold voltage that is relatively low.

Furthermore, referring to FIG. 8, a negative (−) erase voltage V_{ER} may be applied, through the word line WL, to the gate electrode 312 of a memory cell, on which a RESET operation is to be performed, among the gate electrodes 312. Then, the ions 321i in the partial region of the channel layer 323 adjacent in the second direction to the gate electrode 312 to which the negative (−) erase voltage V_{ER} is applied may pass through the electrolyte layer 322 to move to the partial region of the ion reservoir layer 321 adjacent in the second direction to the gate electrode 312 to which the negative (−) erase voltage V_{ER} is applied. Accordingly, the concentration of the donor ions such as oxygen vacancy in the channel layer 323 may be reduced. For example, when the partial region of the channel layer 323 has a second ion concentration that is relatively low, the partial region of the channel layer 323 may have a second resistance that is greater than the first resistance or a second electrical conductivity that is less than the first electrical conductivity. In this case, a transistor including the corresponding gate electrode 312, and the portion of the ion reservoir layer 321, the portion of the electrolyte layer 322, and the portion of the channel layer 323, which are adjacent to one another in the second direction with respect to the gate electrode 312, may have a second threshold voltage that is relatively high. The first threshold voltage may be greater than the erase voltage V_{ER}, the second threshold voltage may be greater than the first threshold voltage, and the write voltage V_{WR} may be greater than the second threshold voltage.

The gate electrodes 312 of the remaining memory cells, on which the SET operation or the RESET operation is not to be performed, among the gate electrodes 312, may be in a floating state in which no voltage is applied thereto. While the gate electrode 312 is in a floating state or a voltage greater than the erase voltage V_{ER} and less than the write voltage V_{WR} is applied to the gate electrode 312, the electrolyte layer 322 serve as a barrier so that the exchange of the ions 321i may not occur between the ion reservoir layer 321 and the channel layer 323. Accordingly, ions are not moved between the region of the ion reservoir layer 321 and the region of the channel layer 323 which are adjacent in the second direction to the gate electrode 312 in a floating state.

Although FIGS. 7 and 8 illustrate only one memory cell as an example, the SET operation or the RESET operation may be independently performed simultaneously on a plurality of memory cells within one memory cell string CS. For example, while the positive (+) write voltage V_{WR} is applied to the gate electrode 312 of one memory cell, the negative (−) erase voltage V_{ER} may be applied to the gate electrode 312 of another adjacent memory cell.

According to an embodiment, the absolute value of a driving voltage, such as the write voltage V_{WR} or the erase voltage V_{ER}, may be less than, for example, a driving voltage of a charge trap flash (CTF) type memory cell string. For example, the absolute value of the driving voltage of the memory cell string CS according to an embodiment may be about 50% to about 70% of the absolute value of the driving voltage of the CTF type memory cell string. For example, the positive (+) write voltage V_{WR} may be about 10 V to about 15 V. Accordingly, as interference between adjacent memory cells is reduced during the SET operation or the RESET operation, the degree of integration of the memory cell string CS according to an embodiment may be increased by reducing the interval between the adjacent memory cells. For example, the interval between adjacent memory cells in the memory cell string CS according to an embodiment may be about 50% to about 70% of the interval between adjacent memory cells of the CTF type memory cell string.

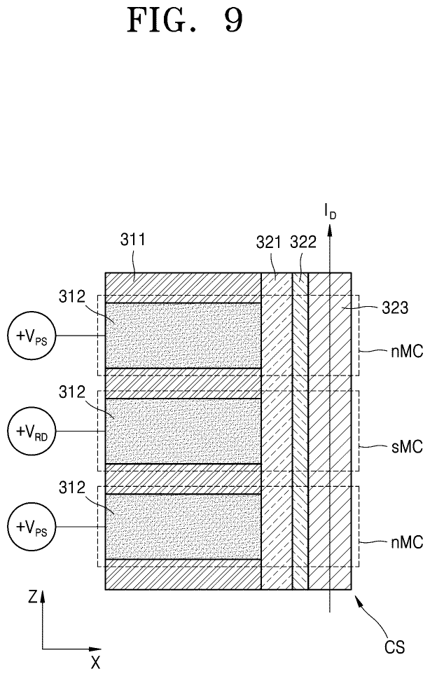

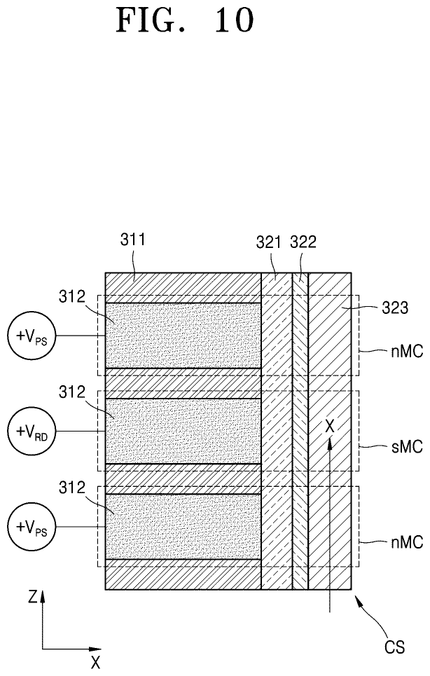

FIGS. 9 and 10 illustrate examples of a read operation on a selected memory cell of the memory cell string CS according to an embodiment. A read operation may be performed by measuring a current I_{D} flowing along the channel layer 323, in a state in which a positive (+) read voltage V_{RD} is applied to only the gate electrodes 312 of a selected memory cell sMC to read data in the memory cell string CS and a positive (+) pass voltage V_{PS} is applied to the gate electrodes 312 of all other non-selected memory cells nMCs. The read voltage V_{RD} may be greater than the erase voltage V_{ER} and less than the second threshold voltage when the ion concentration in the channel layer 323 is relatively low (e.g., when the channel layer 323 has the second ion concentration). For example, the read voltage V_{RD} may be greater than the first threshold voltage when the ion concentration in the channel layer 323 is relatively high (e.g., when the channel layer 323 has the first ion concentration) and less than the second threshold voltage. Furthermore, the pass voltage V_{PS} may be greater than the second threshold voltage when the channel layer 323 has the second ion concentration and less than the write voltage V_{WR}.

Referring to FIG. 9, the transistors of the non-selected memory cells nMCs to which the pass voltage V_{PS} is applied are turned on. When the channel layer 323 of the selected memory cell sMC has the first ion concentration, the transistor of the selected memory cell sMC to which the read voltage V_{RD} is applied is at least partially turned on. Accordingly, as all transistors in the memory cell string CS are turned on, the current I_{D} may flow between a source and a drain along the channel layer 323.

In contrast, referring to FIG. 10, when the channel layer 323 of the selected memory cell sMC has the second ion concentration, the transistor of the selected memory cell sMC to which the read voltage V_{RD} is applied is turned off. In other words, the channel layer 323 of the selected memory cell sMC has a relatively high second resistance. Accordingly, a current hardly flows in the channel layer 323 of the selected memory cell sMC, and as a result, the current Ip hardly flows between the source and the drain of the memory cell string CS. Accordingly, the data written to the selected memory cell sMC may be read through the intensity of the current I_{D} between the source and the drain of the memory cell string CS.

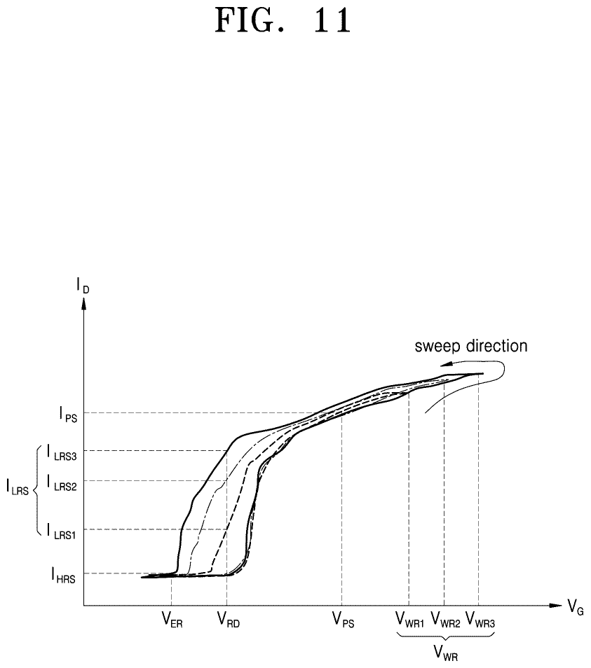

FIG. 11 is a graph showing an example of a driving voltage and voltage-current properties of one memory cell of the memory cell string CS according to an embodiment. Referring to FIG. 11, the driving voltage of the memory cell string CS may have an amplitude order from the erase voltage V_{ER}, the read voltage V_{RD}, the pass voltage V_{PS}, to the write voltage V_{WR}. The erase voltage V_{ER} may be a negative (−) voltage, and the read voltage V_{RD}, the pass voltage V_{PS}, and the write voltage V_{WR} may be positive (+) voltages.

When the memory cell is in an erase state, the channel layer 323 has a relatively high second resistance and a transistor of the memory cell has a relatively high second threshold voltage. In the erase state, when a driving voltage applied to the gate electrodes 312 of the memory cell gradually increases from the erase voltage V_{ER} to the write voltage V_{WR}, the current flowing in the channel layer 323 changes according to a lower path along a sweep direction in the graph of FIG. 11. Accordingly, when the read voltage V_{RD} is applied to the gate electrodes 312 of the memory cell, a high resistance current I_{HRS} flows in the channel layer 323.

When the driving voltage applied to the gate electrodes 312 reaches the write voltage V_{WR}, the memory cell or the channel layer 323 may be in a program state. In this case, the channel layer 323 may have a relatively low first resistance, and the transistor of the memory cell may have a relatively low first threshold voltage. The operation of switching the memory cell or the channel layer 323 to a program state by applying the write voltage V_{WR} to the gate electrodes 312 may be referred to as the SET operation or the program operation.

According to an embodiment, the write voltage V_{WR} may be a plurality of different voltages. For example, the write voltage V_{WR} may include a first write voltage V_{WR1}, a second write voltage V_{WR2} greater than the first write voltage V_{WR1}, and a third write voltage V_{WR3} greater than the second write voltage V_{WR2}. When the first write voltage V_{WR1} is applied to the gate electrodes 312, the channel layer 323 may have a first-1 resistance and the transistor of the memory cell may have a first-1 threshold voltage. When the second write voltage V_{WR2} is applied to the gate electrodes 312, the channel layer 323 may have a first-2 resistance that is less than the first-1 resistance, and the transistor of the memory cell may have a first-2 threshold voltage that is less than first-1 threshold voltage. Furthermore, when the third write voltage V_{WR3} is applied to the gate electrodes 312, the channel layer 323 may have a first-3 resistance that is less than the first-2 resistance, and the transistor of the memory cell may have a first-3 threshold voltage that is less than the first-2 threshold voltage. Then, the memory cell of the memory cell string CS according to an embodiment may operate as a multi-level cell (MLC) in which a multi-level is implemented. According to an embodiment, it may be advantageous to implement an MLC because the amount of ions (e.g., oxygen vacancy) moving to the channel layer 323 according to the voltage applied to the gate electrodes 312 may be relatively easily adjusted.

When the memory cell is in the program state, the current flowing in the channel layer 323 changes according to an upper path in the graph of FIG. 11. For example, when the read voltage V_{RD} is applied to the gate electrodes 312 of the memory cell after the first write voltage V_{WR1} is applied to the gate electrodes 312, a first low resistance current I_{LRS1} flows in the channel layer 323. When the read voltage V_{RD} is applied to the gate electrodes 312 of the memory cell after the second write voltage V_{WR2} is applied to the gate electrodes 312, a second low resistance current I_{LRS2} flows in the channel layer 323. Furthermore, when the read voltage V_{RD} is applied to the gate electrodes 312 of the memory cell after the third write voltage V_{WR3} is applied to the gate electrodes 312, a third low resistance current I_{LRS3} flows in the channel layer 323. The second low resistance current I_{LRS2} may be greater than the first low resistance current I_{LRS1}, and the third low resistance current I_{LRS3} may be less than the second low resistance current I_{LRS2}.

Then, when the erase voltage V_{ER} is applied to the gate electrodes 312 of the memory cell, the memory cell may be in an erase state again. The operation of switching the memory cell or the channel layer 323 to the erase state by applying the erase voltage V_{ER} to the gate electrodes 312 may be referred to as the RESET operation or the erase operation.

The read voltage V_{RD} may be selected such that the current flowing in the channel layer 323 varies depending on the state of a memory cell. When the minimum driving voltage needed to form a conductive path in the channel layer 323 is defined as a threshold voltage, the read voltage V_{RD} may be equal to or slightly greater than the first-1 threshold voltage. When the read voltage V_{RD} is applied to the gate electrodes 312 of the memory cell, the high resistance current I_{HRS} (e.g., a state when the channel layer 323 has the second resistance) or a low resistance current I_{LRS} (e.g., a state when the channel layer 323 has the first resistance) may flow in the channel layer 323 according to the state of the memory cell. The low resistance current I_{LRS} may be greater than the high resistance current I_{HRS}. When the memory cell is an MLC, the low resistance current I_{LRS} flowing in the channel layer 323 may be one of the first low resistance current I_{LRS1}, the second low resistance current I_{LRS2}, and the third low resistance current I_{LRS3}.

In contrast, the pass voltage V_{PS} may be selected such that the current flowing in the channel layer 323 is almost the same regardless of the state of the memory cell. For example, the pass voltage V_{PS} may be greater than the first-1 threshold voltage and the read voltage V_{RD}, and less than the write voltage V_{WR}, in particular the first write voltage V_{WR1}. When the pass voltage V_{PS} is applied to the gate electrodes 312 of the memory cell, a pass current I_{PS} may flow in the channel layer 323 regardless of the state of the memory cell. For example, the substantially same pass current may flow in the channel layer 323 having the first resistance and the channel layer 323 having the second resistance. The pass current I_{PS} may be greater than the low resistance current I_{LRS}. When the memory cell is an MLC, the pass current I_{PS} may be greater than the third low resistance current I_{LRS3}.

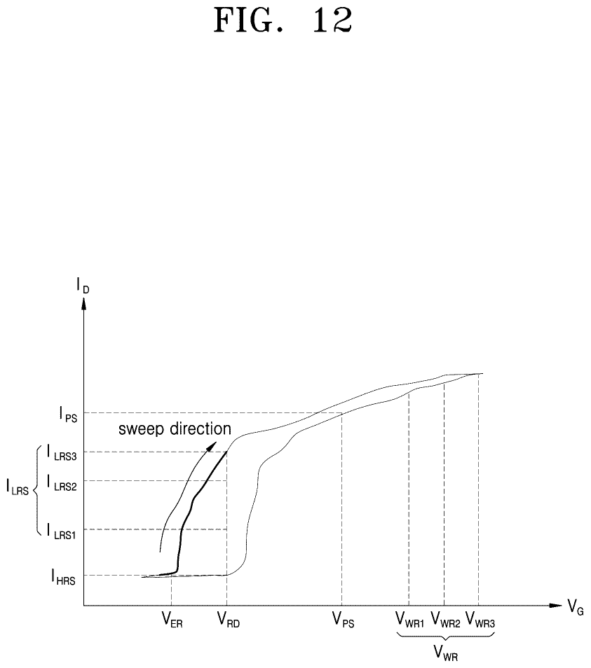

FIG. 12 is a graph showing an example of voltage-current properties after the SET operation of one memory cell of the memory cell string CS according to an embodiment. FIG. 12 shows an example of voltage-current properties, in particular after the third write voltage V_{WR3} is applied to the gate electrodes 312 of the memory cell. Referring to FIG. 12, as the driving voltage applied to the gate electrodes 312 of the memory cell is gradually increased, the current flowing in the channel layer 323 changes according to an upper path along a sweep direction in the graph. When the driving voltage reaches the read voltage V_{RD}, the third low resistance current I_{LRS3} flows in the channel layer 323.

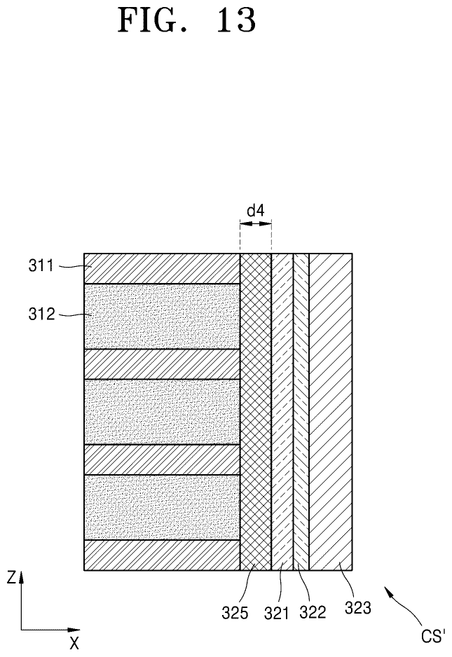

FIG. 13 is a vertical cross-sectional view schematically showing a structure of a memory cell string according to another embodiment. Referring to FIG. 13, a memory cell string CS′ may further include a barrier layer 325 provided between the gate electrodes 312 and the ion reservoir layer 321 and between the spacers 311 and the ion reservoir layer 321. The barrier layer 325 may be conformally deposited along the surfaces of the spacers 311 and the gate electrodes 312 to extend in the first direction, and the ion reservoir layer 321 may be conformally deposited along the surface of the barrier layer 325 to extend in the vertical direction. The barrier layer 325 may prevent or reduce ion exchanges between the ion reservoir layer 321 and the gate electrodes 312 and between the ion reservoir layer 321 and the spacers 311. Accordingly, the reliability of the memory cell string CS′ may be further improved. The barrier layer 325 may include at least one material of silicon oxide (SiO₂), silicon nitride (SiN), and silicon oxynitride (SiON). In addition to the materials described above, the barrier layer 325 may include a chemically stable metal oxide such as aluminum oxide (Al₂O₃). When the barrier layer 325 includes metal oxide, the metal oxide may have an ion (e.g., oxygen vacancy) concentration less than that of the ion reservoir layer 321. The barrier layer 325 may be formed as thin as possible to minimize power loss by the barrier layer 325. For example, a thickness d4 of the barrier layer 325 in the second direction may be greater than 0 nm and less than or equal to about 10 nm.

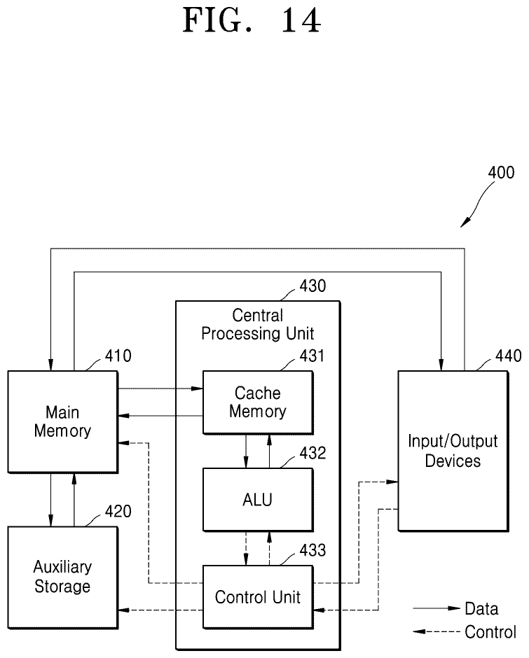

The memory device 200 described above may be used for storing data in various electronic devices. FIG. 14 is a schematic conceptual view of a device architecture applicable to an electronic device 400 including a memory device according to embodiments. Referring to FIG. 14, the electronic device 400 may include a main memory 410, an auxiliary storage 420, a central processing unit (CPU) 430, and an input/output device 440. The CPU 430 may include a cache memory 431, an arithmetic logic unit (ALU) 432, and a control unit 433. The cache memory 431 may include a static random access memory (SRAM). The main memory 410 may include a DRAM device, and the auxiliary storage 420 may include the memory device 200 according to an embodiment. Alternatively, the cache memory 431, the main memory 410, and the auxiliary storage 420 may all include the memory device 100 or 200 according to an embodiment. In some cases, the electronic device 400 may be implemented in the form of computing unit devices and memory unit devices being adjacent to each other in one chip, without distinction of the sub-units described above.

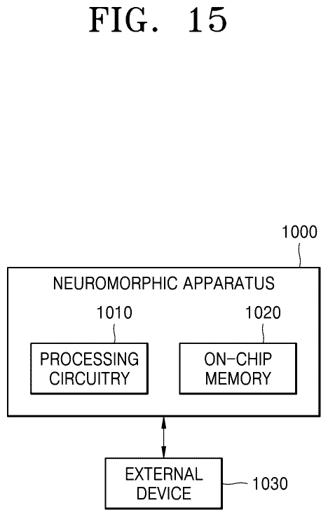

Furthermore, the memory device 200 may be used as a neuromorphic computing platform. For example, FIG. 15 is a schematic block diagram of a neuromorphic apparatus 1000 including the memory device 200 according to an embodiment. Referring to FIG. 15, the neuromorphic apparatus 1000 may include a processing circuitry 1010 and/or a memory 1020. The memory 1020 of the neuromorphic apparatus 1000 may include the memory device 200 according to an embodiment.

The processing circuitry 1010 may be configured to control functions to drive the neuromorphic apparatus 1000. For example, the processing circuitry 1010 may be configured to control the neuromorphic apparatus 1000 by executing a program stored in the memory 1020 of the neuromorphic apparatus 1000. The processing circuitry 1010 may include hardware such as a logic circuit, a combination of hardware such as logic circuits; a hardware/software combination, such as a processor executing software; or a combination thereof. For example, the processor may include a CPU, a graphics processing unit (GPU), an application processor (AP) included in the neuromorphic apparatus 1000, an arithmetic logic unit (ALU), a digital processor, a microcomputer, a field programmable gate array (FPGA), a system-on-chip (SoC), a programmable logic unit, a microprocessor, an application-specific integrated circuit (ASIC), and the like. Furthermore, the processing circuitry 1010 may be configured to read and write various pieces of data from/in an external device 1030 and execute the neuromorphic apparatus 1000 by using the data. The external device 1030 may include a sensor array including an external memory and/or an image sensor (e.g., a CMOS image sensor circuit).

The neuromorphic apparatus 1000 of FIG. 15 may be applied to a machine learning system. Such machine learning systems may utilize various artificial neural network organizational and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Such machine learning systems may include other forms of machine learning models, such as, for example, linear and/or logistic regression, statistical clustering, Bayesian classification, decision trees, dimensionality reduction such as principal component analysis, and expert systems; and/or combinations thereof, including ensembles such as random forests. Such machine learning models may be used to provide various services, for example, an image classify service, a user authentication service based on bio-information or biometric data, an advanced driver assistance system (ADAS) service, a voice assistant service, an automatic speech recognition (ASR) service, or the like, and may be mounted and executed by other electronic devices.

It should be understood that the three-dimensional vertical non-volatile memory device including a memory cell string described above described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A three-dimensional vertical non-volatile memory device comprising:
a plurality of memory cell strings, wherein
the plurality of memory cell strings each include
a channel layer extending in a first direction,
a plurality of gate electrodes and a plurality of spacers alternately arranged in the first direction and each extending in a second direction, the second direction intersecting the first direction,
an ion reservoir layer extending in the first direction between the channel layer and the plurality of gate electrodes and between the channel layer and the plurality of spacers, and
an electrolyte layer extending in the first direction between the channel layer and the ion reservoir layer,
wherein the ion reservoir layer and the channel layer are configured to move ions to each other such that ions are moved from the ion reservoir layer to the channel layer or from the channel layer to the ion reservoir layer according to a voltage applied to the plurality of gate electrodes.

2. The three-dimensional vertical non-volatile memory device of claim 1, wherein the ion reservoir layer and the electrolyte layer each comprise a metal oxide material.

3. The three-dimensional vertical non-volatile memory device of claim 2, wherein a concentration of oxygen vacancy in the ion reservoir layer is greater than a concentration of oxygen vacancy in the electrolyte layer.

4. The three-dimensional vertical non-volatile memory device of claim 2, wherein a composition of the ion reservoir layer is stoichiometrically deficient in oxygen.

5. The three-dimensional vertical non-volatile memory device of claim 2, wherein a ratio of oxygen in a material of the electrolyte layer is greater than a ratio of oxygen in a material of the ion reservoir layer.

6. The three-dimensional vertical non-volatile memory device of claim 2, wherein
the metal oxide material of the ion reservoir layer comprises at least one of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx), and
the metal oxide material of the electrolyte layer comprises at least one of tantalum oxide (TaOx), hafnium oxide (HfOx), aluminum oxide (AlOx), zinc oxide (ZnOx), tungsten oxide (WOx), vanadium (VOx), niobium oxide (NbOx), and nickel oxide (NiOx).

7. The three-dimensional vertical non-volatile memory device of claim 1, wherein the channel layer comprises at least one of indium-gallium-zinc oxide (IGZO), indium-zinc oxide (IZO), gallium-zinc oxide (GZO), zinc-tin oxide (ZTO), indium tungsten oxide (IWO), tungsten oxide (WOx), and zinc oxide (ZnOx).

8. The three-dimensional vertical non-volatile memory device of claim 1, wherein
a thickness of the channel layer in the second direction is in a range from 2 nm to 10 nm, and a thickness of the ion reservoir layer in the second direction is from 2 nm to 10 nm.

9. The three-dimensional vertical non-volatile memory device of claim 1, wherein
a thickness of the electrolyte layer in the second direction is less than a thickness of the ion reservoir layer in the second direction.

10. The three-dimensional vertical non-volatile memory device of claim 1, wherein
the plurality of memory cell strings further comprise a barrier layer,
the barrier layer extends in the first direction between the plurality of gate electrodes and the ion reservoir layer and between the plurality of spacers and the ion reservoir layer.

11. The three-dimensional vertical non-volatile memory device of claim 10, wherein the barrier layer comprises at least one of silicon oxide (SiO₂), silicon nitride (SiN), silicon oxynitride (SiON), and metal oxide.

12. The three-dimensional vertical non-volatile memory device of claim 10, wherein a thickness of the barrier layer in the second direction is greater than 0 nm and less than or equal to 10 nm.

13. The three-dimensional vertical non-volatile memory device of claim 1, wherein,
when a write voltage that is positive is applied to one of the plurality of gate electrodes, ions in a partial region of the ion reservoir layer pass through the electrolyte layer and move to a partial region of the channel layer and the partial region of the channel layer has a first resistance,
the partial region of the ion reservoir layer is adjacent in the second direction to the one of the plurality of gate electrodes to which the write voltage is applied,
the partial region of the channel layer is adjacent in the second direction to the one of the plurality of gate electrodes to which the write voltage is applied.

14. The three-dimensional vertical non-volatile memory device of claim 13, wherein,
when a erase voltage that is negative is applied to the one of the plurality of gate electrodes, ions in the partial region of the channel layer pass through the electrolyte layer and move to the partial region of the ion reservoir layer, and the partial region of the channel layer has a second resistance, and
the second resistance is greater than the first resistance.

15. The three-dimensional vertical non-volatile memory device of claim 14, wherein
the electrolyte layer is configured such that, when a gate electrode among the plurality of gate electrodes is in a floating state, ions are not moved between a region of the ion reservoir layer and a region of the channel layer adjacent in the second direction to the gate electrode in the floating state.

16. The three-dimensional vertical non-volatile memory device of claim 14, wherein
the three-dimensional non-volatile memory device is configured to perform a read operation when a read voltage that is positive is applied to only a selected one of the plurality of gate electrodes and a pass voltage that is positive is applied to non-selected gate electrodes among the plurality of gate electrodes,
the selected one of the plurality of gate electrodes corresponds to a selected memory cell in one of the plurality of memory cell strings from which date is to be read,
the non-selected gate electrodes corresponding to non-selected memory cells in the one of the plurality of memory cell strings,
the read voltage is greater than the erase voltage,
the pass voltage is greater than the read voltage, and
the write voltage is greater than the pass voltage.

17. The three-dimensional vertical non-volatile memory device of claim 16, wherein
when the read voltage is applied to the plurality of gate electrodes and the channel layer has the first resistance, a low resistance current flows in the channel layer having the first resistance,
when the read voltage is applied to the plurality of gate electrodes and the channel layer has the second resistance, and a high resistance current flows in the channel layer having the second resistance, and
when the pass voltage is applied to the plurality of gate electrodes and the channel layer has either the first resistance or the second resistance, a same pass current flows in the channel layer having either the first resistance or the second resistance.

18. The three-dimensional vertical non-volatile memory device of claim 17, wherein
the low resistance current is greater than the high resistance current, and
the pass current is greater than the high resistance current.

19. The three-dimensional vertical non-volatile memory device of claim 13, wherein
the write voltage comprises a first write voltage and a second write voltage,
the second write voltage is greater than the first write voltage, and
when the first write voltage is applied to one of the plurality of gate electrodes, a partial region of the channel layer adjacent in the second direction to the one of the plurality of gate electrodes to which the first write voltage is applied has a first-1 resistance,
when the second write voltage is applied to one of the plurality of gate electrodes, a partial region of the channel layer adjacent in the second direction to the one of the plurality of gate electrodes to which the second write voltage is applied has a first-2 resistance, and
the first-2 resistance is less than the first-1 resistance.

20. An electronic device comprising:
processing circuitry; and
a three-dimensional vertical non-volatile memory device connected to the processing circuitry, wherein
the three-dimensional vertical non-volatile memory device includes a plurality of memory cell strings, and
the plurality of memory cell strings include
a channel layer extending in a first direction,
a plurality of gate electrodes and a plurality of spacers alternately arranged in the first direction and each extending in a second direction, the second direction intersecting the first direction,
an ion reservoir layer extending in the first direction between the channel layer and the plurality of gate electrodes and between the channel layer and the plurality of spacers, and
an electrolyte layer extending in the first direction between the channel layer and the ion reservoir layer,
wherein the ion reservoir layer and the channel layer are configured to move ions such that ions are moved from the ion reservoir layer to the channel layer or from the channel layer to the ion reservoir layer, according to a voltage applied to the plurality of gate electrodes.
